(19) United States
(12) Patent Application Publication
(10) Pub. No.: US 2025/0185492 A1
(43) Pub. Date: Jun. 5, 2025

(54) Display Apparatus

(71) Applicant: Samsung Display Co., Ltd., Yongin-Si, Gyeonggi-Do (KR)

(72) Inventors: Jungi KIM, Yongin-si, Gyeonggi-do (KR); Taewook KANG, Yongin-si, Gyeonggi-do (KR); Sanghyun YUN, Yongin-si, Gyeonggi-do (KR); Pilsoon HONG, Yongin-si, Gyeonggi-do (KR)

(21) Appl. No.: 18/611,703

(22) Filed: Mar. 21, 2024

(30) Foreign Application Priority Data
Mar. 24, 2023 (KR) 10-2023-0039090
Jun. 13, 2023 (KR) 10-2023-0075544

(51) Int. Cl. H10K 59/80; H10K 59/122; H10K 59/38; H10K 59/40; H10K 59/65

(52) U.S. Cl. CPC H10K 59/879; H10K 59/122; H10K 59/38; H10K 59/40; H10K 59/65; H10K 59/873; H10K 59/8792

(57) ABSTRACT

A display apparatus is disclosed that includes a substrate including an optical functional layer disposed on a first light-emitting device and a first light-receiving device, wherein the optical functional layer includes a first functional layer including a first middle opening and a second middle opening, and a second functional layer disposed on the first functional layer and having a refractive index greater than a refractive index of the first functional layer, and a slope of a side surface of the first functional layer, facing the first middle opening, is different from a slope of a side surface of the first functional layer, facing the second middle opening.

### CROSS-REFERENCE TO RELATED APPLICATIONS

This application is based on and claims priority under 35 U.S.C. § 119 to Korean Patent Application Nos. 10-2023-0039090, filed on Mar. 24, 2023, and 10-2023-0075544, filed on Jun. 13, 2023, in the Korean Intellectual Property Office, the disclosures of which are incorporated by reference herein in their entirety.

### BACKGROUND

### 1. Field

One or more embodiments relate to a structure of a display apparatus.

### 2. Description of the Related Art

In general, display apparatuses include a light-emitting device, such as an organic light-emitting diode, and a thin-film transistor on a substrate and operate by allowing display elements to emit light.

Specifically, each pixel of display apparatuses has a light-emitting device such as an organic light-emitting diode in which an intermediate layer including an emission layer is arranged between a pixel electrode and an opposite electrode. Display apparatuses generally control whether or not each pixel emits light or the degree of light emission via a thin-film transistor electrically connected to a pixel electrode. Some layers included in an intermediate layer of a display element are commonly provided in a plurality of light-emitting devices.

### SUMMARY

One or more embodiments may provide a display apparatus including a light-emitting device having increased luminescence efficiency and a light-receiving device having increased light-receiving efficiency. However, these embodiments are only examples, and the scope of the disclosure is not limited thereto.

Additional aspects will be set forth in part in the description which follows and, in part, will be apparent from the description, or may be learned by practice of the presented embodiments of the disclosure.

According to one or more embodiments, a display apparatus includes a substrate including a first emission region and a first sensing region, a first light-emitting device disposed on the substrate and corresponding to the first emission region, a first light-receiving device disposed on the substrate and corresponding to the first sensing region, and an optical functional layer disposed on the first light-emitting device and the first light-receiving device, wherein the optical functional layer includes a first functional layer including a first middle opening overlapping the first emission region and a second middle opening overlapping the first sensing region, and a second functional layer disposed on the first functional layer and having a refractive index greater than a refractive index of the first functional layer, the first functional layer includes a first angle between a first side surface facing the first middle opening and a lower surface of the first functional layer, and a second angle between a second side surface facing the second middle opening and the lower surface of the first functional layer, and the first angle is greater than the second angle.

In an embodiment, the first side surface and the second side surface of the first functional layer may each include a forward tapered slope.

In an embodiment, the first angle may be about 70° to about 90°.

In an embodiment, the second angle may be about 30° to about 70°.

In an embodiment, a difference between the refractive index of the second functional layer and the refractive index of the first functional layer may be about 0.05 to about 0.3.

In an embodiment, the refractive index of the first functional layer may be about 1.3 to about 1.6, and the refractive index of the second functional layer may be about 1.6 to about 1.85.

In an embodiment, the display apparatus may further include a bank layer arranged between the substrate and the optical functional layer, wherein the bank layer may include a first lower opening covering an edge of a first pixel electrode included in the first light-emitting device and exposing a central portion of the first pixel electrode, and a second lower opening covering an edge of a first sensing electrode included in the first light-receiving device and exposing a central portion of the first sensing electrode, and the first lower opening may overlap the first middle opening, and the second lower opening may overlap the second middle opening.

In an embodiment, when viewed in a direction perpendicular to the substrate, a width of the first middle opening may be greater than a width of the first lower opening, and a width of the second middle opening may be greater than a width of the second lower opening.

In an embodiment, a height of the optical functional layer may be about 1.5 μm to about 5 μm, based on a thickness direction of the substrate.

In an embodiment, a height of the first functional layer and a height of the second functional layer may be equal to each other, based on a thickness direction of the substrate.

In an embodiment, a height of the second functional layer may be greater than a height of the first functional layer, based on a thickness direction of the substrate.

In an embodiment, the second functional layer may fill the first middle opening and the second middle opening and cover an upper surface of the first functional layer.

In an embodiment, the display apparatus may further include a light-blocking layer disposed on the optical functional layer and including a first upper opening overlapping the first middle opening and a second upper opening overlapping the second middle opening, and a color filter including a first color filter filling the first upper opening and a second color filter filling the second upper opening.

In an embodiment, a lower surface of the light-blocking layer may be in direct contact with an upper surface of the first functional layer.

In an embodiment, the second functional layer may be arranged between the lower surface of the light-blocking layer and the upper surface of the first functional layer.

In an embodiment, a material of the second functional layer, which fills the first middle opening, may be identical to that of the first color filter, and a material of the second functional layer, which fills the second middle opening, may be identical to that of the second color filter.

In an embodiment, the display apparatus may further include a thin-film encapsulation layer covering the first light-emitting device and the first light-receiving device, and an input sensing layer arranged between the thin-film encapsulation layer and the optical functional layer.

In an embodiment, the input sensing layer may include a conductive layer forming the touch electrode, and the first functional layer may overlap the conductive layer.

According to one or more embodiments, a display apparatus includes a first electrode and a second electrode arranged adjacent to the first electrode, a bank layer including a first lower opening overlapping the first electrode and a second lower opening overlapping the second electrode, an opposite electrode disposed on the bank layer, a thin-film encapsulation layer disposed on the opposite electrode, and an optical functional layer disposed on the thin-film encapsulation layer, wherein the optical functional layer includes a first functional layer including a first middle opening overlapping the first lower opening and a second middle opening overlapping the second lower opening, and a second functional layer disposed on the first functional layer and having a refractive index greater than a refractive index of the first functional layer, the first functional layer includes a first angle between a first side surface facing the first middle opening and a lower surface of the first functional layer, and a second angle between a second side surface facing the second middle opening and the lower surface of the first functional layer, and the first angle is greater than the second angle.

In an embodiment, an emission layer emitting light may be arranged in the first lower opening, and an activation layer detecting light may be arranged in the second lower opening.

In an embodiment, the first angle may be about 70° to abut 90°, and the second angle may be about 30° to about 60°.

In an embodiment, a difference between the refractive index of the second functional layer and the refractive index of the first functional layer may be about 0.05 to about 0.3.

In an embodiment, the display apparatus may further include an input sensing layer arranged between the thin-film encapsulation layer and the optical functional layer, and the first functional layer may be arranged to overlap a touch electrode of the input sensing layer.

In an embodiment, the display apparatus may further include a light-blocking layer disposed on the optical functional layer and including a first upper opening overlapping the first middle opening and a second upper opening overlapping the second middle opening, and a first color filter filling the first upper opening and a second color filter filling the second upper opening.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a schematic plan view of a portion of a display apparatus according to an embodiment;

FIG. 2 is a schematic cross-sectional view of a cross-section of the display apparatus of FIG. 1 taken along line A-A′ of FIG. 1;

FIG. 3 is a schematic cross-sectional view of a display panel of a display apparatus, according to an embodiment;

FIG. 4 is an equivalent circuit diagram of a pixel circuit electrically connected to a light-emitting device included in one pixel of a display apparatus, according to an embodiment;

FIG. 5 is a schematic cross-sectional view of a portion of a display apparatus according to an embodiment;

FIG. 6 is a schematic plan view of an input sensing layer of a display apparatus, according to an embodiment;

FIG. 7 is a schematic plan view of a portion of a display apparatus according to an embodiment and is an enlarged schematic plan view of portion B of FIG. 1;

FIG. 8 is a schematic cross-sectional view of a portion of a display apparatus according to an embodiment and corresponds to a cross-section of the display apparatus of FIG. 7 taken along line C-C′ of FIG. 7;

FIG. 9 illustrates a traveling path of light emitted from the display apparatus shown in FIG. 8;

FIG. 10 is a schematic cross-sectional view of a portion of a display apparatus according to another embodiment; and

FIG. 11 is a schematic cross-sectional view of a portion of a display apparatus according to another embodiment.

### DETAILED DESCRIPTION

Reference will now be made in detail to embodiments, examples of which are illustrated in the accompanying drawings, wherein like reference numerals refer to like elements throughout the specification. In this regard, the present embodiments may have different forms and should not be construed as being limited to the descriptions set forth herein. Accordingly, the embodiments are merely described below, by referring to the figures, to explain aspects of the present description.

As used herein, the word “or” means logical “or” so that, unless the context indicates otherwise, the expression “A, B, or C” means “A and B and C,” “A and B but not C,” “A and C but not B,” “B and C but not A,” “A but not B and not C,” “B but not A and not C,” and “C but not A and not B.” Throughout the disclosure, the expression “at least one of a, b or c” indicates only a, only b, only c, both a and b, both a and c, both b and c, all of a, b, and c, or variations thereof.

Various modifications may be applied to the present embodiments, and particular embodiments will be illustrated in the drawings and described in the detailed description section. The effect and features of the present embodiments, and a method to achieve the same, will be clearer referring to the detailed descriptions below with the drawings. However, the present embodiments may be implemented in various forms, not by being limited to the embodiments presented below.

Hereinafter, embodiments will be described, in detail, with reference to the accompanying drawings, and in the description with reference to the drawings, the same or corresponding components are indicated by the same reference numerals and redundant descriptions thereof are omitted.

In the following embodiment, it will be understood that although the terms “first,” “second,” etc. may be used herein to describe various components, these components should not be limited by these terms. These terms are only used to distinguish one component from another.

In the following embodiment, the expression of singularity in the present specification includes the expression of plurality unless clearly specified otherwise in context.

In the following embodiment, it will be further understood that the terms “comprises” and “includes” (as well as their variations such as “comprising”) used herein specify the presence of stated features or components, but do not preclude the presence or addition of one or more other features or components.

In the following embodiment, it will be understood that when a layer, region, or component is referred to as being “formed on” another layer, region, or component, it can be directly or indirectly formed on the other layer, region, or component. That is, for example, intervening layers, regions, or components may be present.

Sizes of components in the drawings may be exaggerated for convenience of explanation. In other words, since sizes and thicknesses of components in the drawings are arbitrarily illustrated for convenience of explanation, the following embodiments are not limited thereto.

When a certain embodiment may be implemented differently, a specific process order may be performed differently from the described order. For example, two consecutively described processes may be performed substantially at the same time or performed in an order opposite to the described order.

In the following embodiment, it will be understood that when a layer, region, or component is connected to another layer, region, or component, the layers, regions or components may not only be directly connected, but may also be indirectly connected via another layer, region, or component therebetween. For example, in the present specification, when a layer, region, or component is electrically connected to another layer, region, or component, the layers, regions, or components may not only be directly electrically connected, but may also be indirectly electrically connected via another layer, region, or component therebetween.

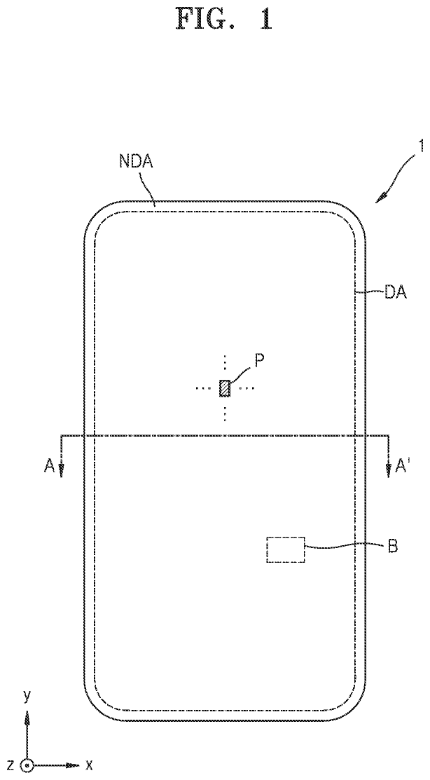

FIG. 1 is a schematic plan view of a portion of a display apparatus according to an embodiment.

Referring to FIG. 1, a display apparatus 1 includes a display region DA and a peripheral region NDA located outside of the display region DA. A plurality of pixels P including display elements are arranged in the display region DA, and the display apparatus 1 may provide an image by using light emitted from the plurality of pixels P arranged in the display region DA. The peripheral region NDA is a kind of non-display region in which display elements are not arranged, and the display region DA may be entirely surrounded by the peripheral region NDA.

FIG. 1 illustrates the display apparatus 1 including a flat display surface, but the disclosure is not limited thereto. In some embodiments, the display apparatus 1 may include a three-dimensional display surface or a curved display surface.

When the display apparatus 1 includes a three-dimensional display surface, the display apparatus 1 may include a plurality of display regions indicating different directions and may include, for example, a polygonal columnar display surface. In some embodiments, when the display apparatus 1 includes a curved display surface, the display apparatus 1 may be implemented in various forms such as a flexible, foldable, and rollable display apparatus.

In addition, in an embodiment, FIG. 1 illustrates the display apparatus 1 which may be applied to a portable phone terminal. Although not shown, electronic modules, camera modules, power modules, and the like, which are mounted on a mainboard, may be arranged together with the display apparatus 1 in a bracket/case or the like to form a portable phone terminal. The display apparatus 1 according to the disclosure may be applied to large-sized electronic apparatuses such as televisions and monitors, as well as small and medium-sized electronic apparatuses such as tablet PCs, car navigation devices, game consoles, and smart watches.

FIG. 1 illustrates a case where the display region DA of the display apparatus 1 is a rectangle with rounded corners, but in some embodiments, the shape of the display region DA may be a circle, an ellipse, or a polygon such as a triangle or a pentagon.

Hereinafter, as the display apparatus 1 according to an embodiment, an organic light-emitting display apparatus is described as an example, but the display apparatus 1 of the disclosure is not limited thereto. In some embodiments, the display apparatus 1 of the disclosure may be an inorganic light-emitting display (or inorganic electroluminescent (EL) display) or a quantum dot light-emitting display. For example, an emission layer of a display element provided in the display apparatus 1 may include an organic material, an inorganic material, a quantum dot, an organic material and a quantum dot, or an inorganic material and a quantum dot.

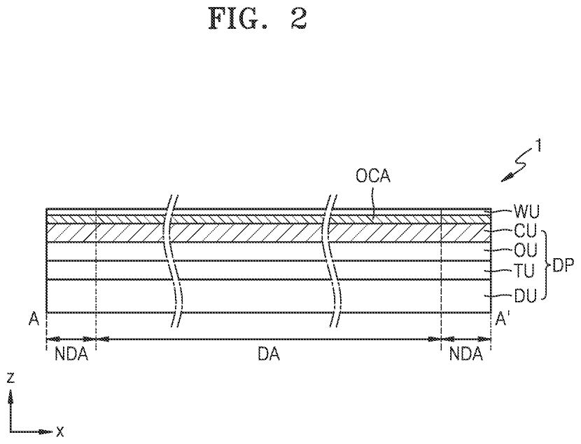

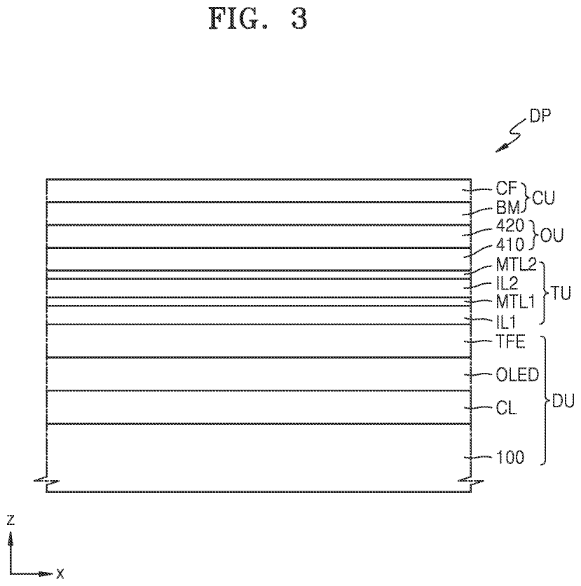

FIG. 2 is a schematic cross-sectional view of a cross-section of the display apparatus 1 of FIG. 1 taken along line A-A′ of FIG. 1, and FIG. 3 is a schematic cross-sectional view of a display panel of the display apparatus 1 according to an embodiment. FIGS. 2 and 3 are simply illustrated to describe a stacking relationship of functional panels and functional layers of the display apparatus 1.

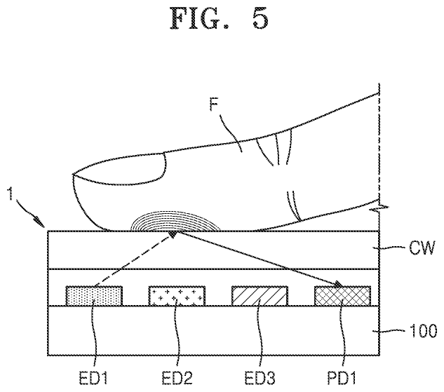

Referring to FIG. 2, the display apparatus 1 according to an embodiment may include a display layer DU, an input sensing layer TU, an optical functional layer OU, a color filter layer CU, and a window layer WU. At least some of components among the display layer DU, the input sensing layer TU, the optical functional layer OU, the color filter layer CU, and the window layer WU may be formed by a continuous process, or at least some of the components may be bonded to each other via an adhesive member. In FIG. 2, as the adhesive member, an optically clear adhesive member OCA is shown as an example. The adhesive member described hereinafter may include a common adhesive. In an embodiment, the window layer WU may include a cover window CW (FIG. 5). The window layer WU may be replaced with other components or may be omitted.

In an embodiment, the input sensing layer TU may be directly disposed on the display layer DU. Throughout the specification, the expression “component B is directly disposed on component A” may be to mean that a separate adhesive layer/adhesive member is not arranged between component A and component B. After component A is formed, component B is formed on a base surface provided by component A via a continuous process.

In an embodiment, a structure including the display layer DU, the input sensing layer TU directly disposed on the display layer DU, the optical functional layer OU, and the color filter layer CU may be defined as a display panel DP. For example, as shown in FIG. 2, the optically clear adhesive member OCA may be arranged between the display panel DP and the window layer WU.

The display layer DU generates an image, and the input sensing layer TU obtains coordinate information of an external input (for example, a touch event). Although not shown separately, the display panel DP according to an embodiment may further include a protection member disposed on a lower surface of the display layer DU. The protection member and the display layer DU may be bonded via an adhesive member.

The optical functional layer OU may increase light efficiency. The optical functional layer OU may improve front light efficiency or side visibility of light emitted from a light-emitting device, for example, an organic light-emitting diode OLED.

The color filter layer CU may be arranged between the optical functional layer OU and the window layer WU. The color filter layer CU may include a color filter provided to correspond to an emission region of each pixel P and a light-blocking layer provided to correspond to a non-emission region between the pixels P.

Hereinafter, structures of the display layer DU, the input sensing layer TU, the optical functional layer OU, and the color filter layer CU are described in detail with reference to FIG. 3. Referring to FIG. 3, the display panel DP includes the display layer DU, the input sensing layer TU, the optical functional layer OU, and the color filter layer CU.

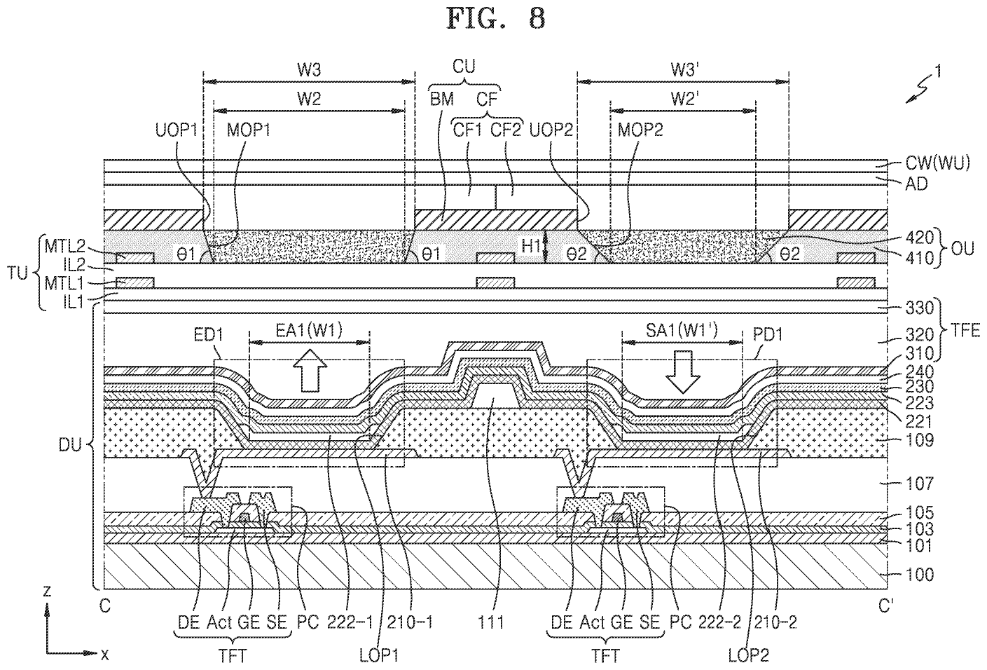

In the display layer DU, a circuit layer CL, a light-emitting device (for example, the organic light-emitting diode OLED), and a thin-film encapsulation layer TFE may be sequentially disposed on a substrate 100. The input sensing layer TU may be directly disposed on the thin-film encapsulation layer TFE. The thin-film encapsulation layer TFE includes at least one organic encapsulation layer 320 (FIG. 8), and thus may provide a more planarized base surface. Therefore, even when components of the input sensing layer TU are formed by a continuous process, their defect rate may be reduced.

The input sensing layer TU may have a multilayer structure. The input sensing layer TU includes a touch electrode, a trace line connected to the touch electrode, and at least one insulating layer. The input sensing layer TU may sense an external input by using, for example, a capacitance method. In the disclosure, an operation method of the input sensing layer TU is not particularly limited, and in an embodiment, the input sensing layer TU may sense an external input by using an electromagnetic induction method or a pressure sensing method.

As shown in FIG. 3, the input sensing layer TU according to an embodiment may include a first inorganic insulating layer IL1, a first conductive layer MTL1, a second inorganic insulating layer IL2, and a second conductive layer MTL2.

For example, each of the first conductive layer MTL1 and the second conductive layer MTL2 may have a single-layered structure or may have a multilayer structure. A conductive layer of the single-layered structure may include a metal layer or a transparent conductive layer. The metal layer may include molybdenum, silver, titanium, copper, aluminum, and an alloy thereof. The transparent conductive layer may include a transparent conductive oxide such as indium tin oxide (ITO), indium zinc oxide (IZO), zinc oxide (ZnO), or indium tin zinc oxide (ITZO). In addition, the transparent conductive layer may include a conductive polymer such as PEDOT, a metal nanowire, or graphene.

A conductive layer of the multilayer structure may include a plurality of metal layers. Each of the plurality of metal layers may have, for example, a three-layer structure of Ti/Al/Ti. The conductive layer of the multilayer structure may include at least one metal layer and at least one transparent conductive layer.

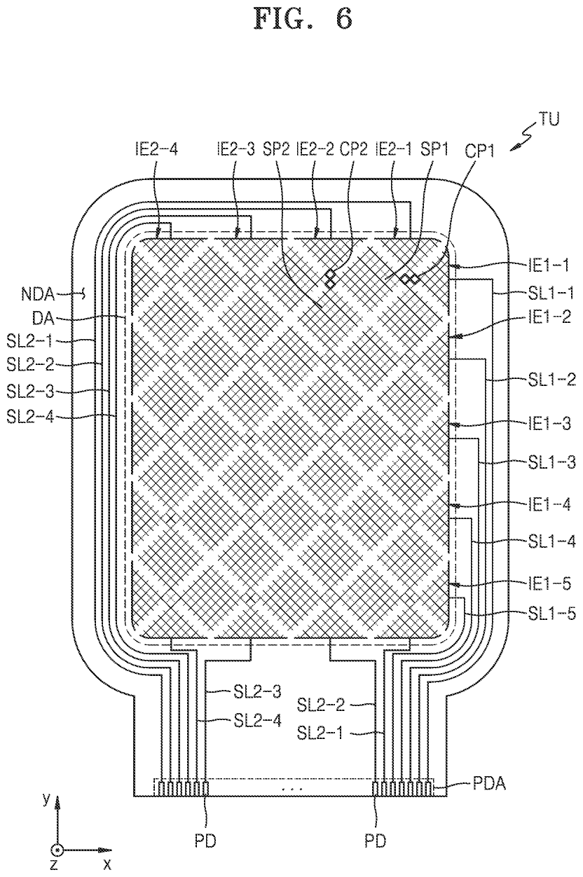

Each of the first conductive layer MTL1 and the second conductive layer MTL2 includes a plurality of patterns. Hereinafter, the first conductive layer MTL1 may include first conductive patterns, and the second conductive layer MTL2 may include second conductive patterns. The first conductive patterns and the second conductive patterns may form a touch electrode shown in FIG. 6. In an embodiment, the touch electrode may have a mesh shape, as described below with reference to FIG. 6, so as not to be visible to a user.

Each of the first inorganic insulating layer IL1 and the second inorganic insulating layer IL2 may have a single-layered or multilayer structure. Each of the first inorganic insulating layer IL1 and the second inorganic insulating layer IL2 may include an inorganic material or a composite material. For example, at least one of the first inorganic insulating layer IL1 and the second inorganic insulating layer IL2 may include an inorganic film. The inorganic film may include at least one of aluminum oxide, titanium oxide, silicon oxide, silicon oxynitride, zirconium oxide, and hafnium oxide. In some embodiments, the first inorganic insulating layer IL1 or the second inorganic insulating layer IL2 may be replaced with an organic insulating layer.

The optical functional layer OU may be directly disposed on the input sensing layer TU. The optical functional layer OU may include a first functional layer 410 and a second functional layer 420 on the first functional layer 410. The first functional layer 410 and the second functional layer 420 may each include an organic insulating material and may have different refractive indices. In an embodiment, a refractive index of the second functional layer 420 may be greater than a refractive index of the first functional layer 410.

The color filter layer CU may be directly disposed on the optical functional layer OU. The color filter layer CU may include a light-blocking layer BM and a color filter CF on the light-blocking layer BM. The light-blocking layer BM may be a black matrix which at least partially absorbs externally reflected light or internally reflected light. The color filter CF may have a color corresponding to light emitted from an emission layer under the color filter CF.

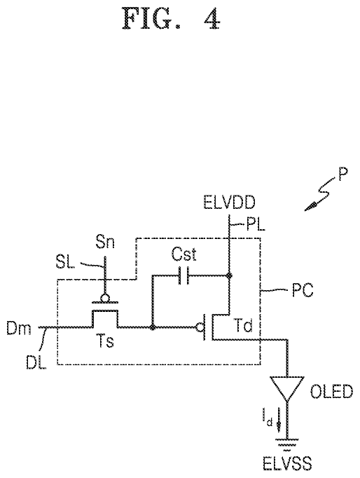

FIG. 4 is an equivalent circuit diagram of a pixel circuit electrically connected to a light-emitting device included in one pixel of a display apparatus, according to an embodiment.

Referring to FIG. 4, each pixel P includes a pixel circuit PC connected to a scan line SL and a data line DL, and a light-emitting device (for example, the organic light-emitting diode OLED) connected to the pixel circuit PC.

The pixel circuit PC includes a driving thin-film transistor Td, a switching thin-film transistor Ts, and a storage capacitor Cst. The switching thin-film transistor Ts is connected to the scan line SL and the data line DL and is configured to transmit a data signal Dm input via the data line DL to the driving thin-film transistor Td according to a scan signal Sn input via the scan line SL.

The storage capacitor Cst is connected to the switching thin-film transistor Ts and a driving voltage line PL and is configured to store a voltage corresponding to a difference between a voltage received from the switching thin-film transistor Ts and a driving voltage ELVDD supplied to the driving voltage line PL.

The driving thin-film transistor Td is connected to the driving voltage line PL and the storage capacitor Cst and may be configured to control a driving current flowing from the driving voltage line PL to the organic light-emitting diode OLED, according to a voltage value stored in the storage capacitor Cst. The organic light-emitting diode OLED may emit light having a certain luminance by a driving current Id.

FIG. 4 illustrates a case where the pixel circuit PC includes two thin-film transistors and one storage capacitor, but the disclosure is not limited thereto. In some embodiments, the pixel circuit PC may include seven thin-film transistors and one storage capacitor. In some embodiments, the pixel circuit PC may include at least two storage capacitors.

FIG. 5 is a schematic cross-sectional view of a portion of a display apparatus according to an embodiment.

Referring to FIG. 5, the display apparatus 1 according to an embodiment may include a first light-emitting device ED1, a second light-emitting device ED2, a third light-emitting device ED3, and a first light-receiving device PD1. The first light-emitting device ED1, the second light-emitting device ED2, and the third light-emitting device ED3 may emit different light. For example, the first light-emitting device ED1 may emit green light, the second light-emitting device ED2 may emit red light, and the third light-emitting device ED3 may emit blue light.

As shown in FIG. 5, the display apparatus 1 may have a function of sensing an object, for example, a fingerprint of a finger F, which is in contact with the cover window CW. When at least a portion of reflected light reflected by a user's fingerprint among light emitted from at least one of the first light-emitting device ED1, the second light-emitting device ED2, and the third light-emitting device ED3 is incident on the first light-receiving device PD1, the first light-receiving device PD1 may detect the reflected light. For example, when the green light emitted from the first light-emitting device ED1 is reflected by an object which is in contact with the cover window CW, and incident on the first light-receiving device PD1, the first light-receiving device PD1 may detect the reflected green light.

FIG. 6 is a schematic plan view of an input sensing layer of a display apparatus, according to an embodiment.

As shown in FIG. 6, the input sensing layer TU may include first touch electrodes IE1-1 to IE1-5, first trace lines SL1-1 to SL1-5 connected to the first touch electrodes IE1-1 to IE1-5, second touch electrodes IE2-1 to IE2-4, and second trace lines SL2-1 to SL2-4 connected to the second touch electrodes IE2-1 to IE2-4. Although not shown, the input sensing layer TU may further include an optical dummy electrode arranged in a boundary region between the first touch electrodes IE1-1 to IE1-5 and the second touch electrodes IE2-1 to IE2-4.

The thin-film encapsulation layer TFE shown in FIG. 3 includes the at least one organic encapsulation layer 320 (see FIG. 8), and thus may provide a more planarized base surface. Therefore, even when the components of the input sensing layer TU are formed by a continuous process, their defect rate may be reduced. The first trace lines SL1-1 to SL1-5 and the second trace lines SL2-1 to SL2-4 are arranged in the peripheral region NDA having a reduced step difference, and thus may each have a uniform thickness. Accordingly, stress in the first trace lines SL1-1 to SL1-5 and the second trace lines SL2-1 to SL2-4, caused by a step difference in a lower film, may be reduced.

The first touch electrodes IE1-1 to IE1-5 and the second touch electrodes IE2-1 to IE2-4 cross each other. The first touch electrodes IE1-1 to IE1-5 are arranged in a second direction (for example, y direction), and each of the first touch electrodes IE1-1 to IE1-5 may extend in a first direction (for example, x direction). The second touch electrodes IE2-1 to IE2-4 are arranged in the first direction (for example, x direction), and each of the second touch electrodes IE2-1 to IE2-4 may extend in the second direction (for example, y direction).

Each of the first touch electrodes IE1-1 to IE1-5 includes first sensor portions SP1 and first connection portions CP1. Each of the second touch electrodes IE2-1 to IE2-4 includes second sensor portions SP2 and second connection portions CP2. Two first sensor portions arranged at both ends of a first touch electrode among the first sensor portions SP1 may have a smaller size than that of a first sensor portion arranged at the center, for example, ½ the size thereof. Two second sensor portions arranged at both ends of a second touch electrode among the second sensor portions SP2 may have a smaller size than that of a second sensor portion arranged at the center, for example, ½ the size thereof.

FIG. 6 illustrates the first touch electrodes IE1-1 to IE1-5 and the second touch electrodes IE2-1 to IE2-4 according to an embodiment, but their shapes are not limited. In an embodiment, the first touch electrodes IE1-1 to IE1-5 and the second touch electrodes IE2-1 to IE2-4 may each have a shape (for example, a bar shape) in which a sensor portion and a connection portion are not distinguished). The first sensor portions SP1 and the second sensor portions SP2, each having a rhombus shape, are illustrated as an example, but the disclosure is not limited thereto, and the first sensor portions SP1 and the second sensor portions SP2 may each also have a polygonal shape.

The first sensor portions SP1 are arranged in the first direction (for example, x direction) within one first touch electrode, and the second sensor portions SP2 are arranged in the second direction (for example, y direction) within one second touch electrode. Each of the first connection portions CP1 connects adjacent first sensor portions SP1 to each other, and each of the second connection portions CP2 connects adjacent second sensor portions SP2 to each other.

The first trace lines SL1-1 to SL1-5 are connected to one end of each of the first touch electrodes IE1-1 to IE1-5, respectively. The second trace lines SL2-1 to SL2-4 are connected to both ends of the second touch electrodes IE2-1 to IE2-4. In some embodiments, the first trace lines SL1-1 to SL1-5 may also be connected to both ends of the first touch electrodes IE1-1 to IE1-5. In some embodiments, the second trace lines SL2-1 to SL2-4 may be connected only to one end of each of the second touch electrodes IE2-1 to IE2-4, respectively.

The first trace lines SL1-1 to SL1-5 and the second trace lines SL2-1 to SL2-4 may be connected to a pad unit PD arranged on one side. The pad unit PD may be aligned in a pad region PDA.

In an embodiment, the positions of the first trace lines SL1-1 to SL1-5 and the second trace lines SL2-1 to SL2-4 may be switched. Unlike shown in FIG. 6, the first trace lines SL1-1 to SL1-5 may be arranged on the left side, and the second trace lines SL2-1 to SL2-4 may bae arranged on the right side.

Referring to FIG. 6, in the present embodiment, the first touch electrodes IE1-1 to IE1-5 and the second touch electrodes IE2-1 to IE2-4 may each have a mesh shape. As the first touch electrodes IE1-1 to IE1-5 and the second touch electrodes IE2-1 to IE2-4 each have a mesh shape, parasitic capacitance with electrodes (for example, an opposite electrode) of the display layer DU (FIG. 2) may be reduced. In addition, as described below, the first touch electrodes IE1-1 to IE1-5 and the second touch electrodes IE2-1 to IE2-4 do not overlap an emission region, and thus may not be visible to a user of the display apparatus 1.

The first touch electrodes IE1-1 to IE1-5 and the second touch electrodes IE2-1 to IE2-4, each having a mesh shape, may be formed of a metal which may be processed at a low temperature, and may include, for example, silver, aluminum, copper, chrome, nickel, or titanium. Therefore, even when the input sensing layer TU is formed via a continuous process, damage to a light-emitting device may be prevented.

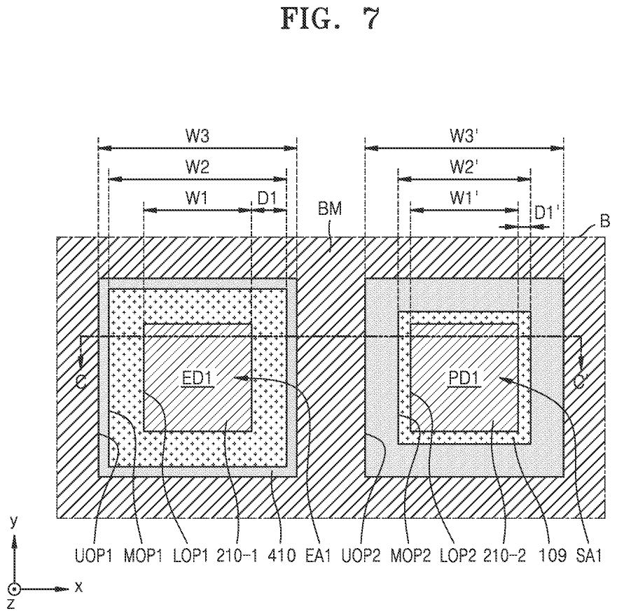

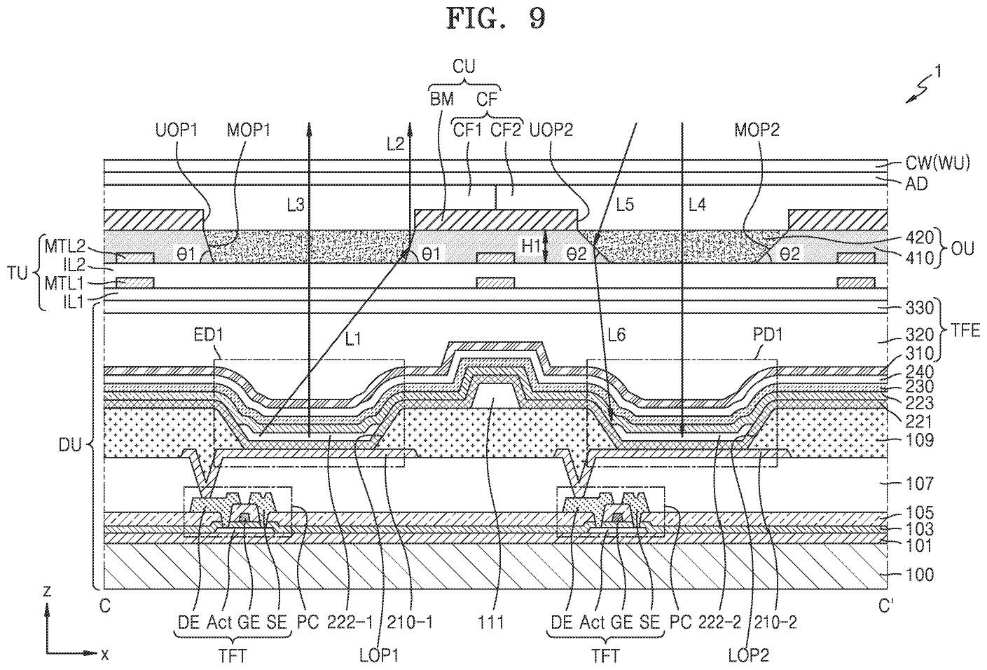

FIG. 7 is a schematic plan view of a portion of a display apparatus according to an embodiment and is an enlarged schematic plan view of portion B of FIG. 1. In FIG. 7, a plan view on the light-blocking layer BM is shown for convenience. FIG. 8 is a schematic cross-sectional view of a portion of a display apparatus according to an embodiment and corresponds to a cross-section of the display apparatus of FIG. 7 taken along line C-C′ of FIG. 7. FIG. 9 illustrates a traveling path of light emitted from the display apparatus shown in FIG. 8.

First, referring to FIG. 7, the display apparatus 1 may include a plurality of light-emitting devices and a plurality of light-receiving devices. The plurality of light-emitting device may include the first light-emitting device ED1, the second light-emitting device ED2 (FIG. 5), and the third light-emitting device ED3 (FIG. 5), and the plurality of light-receiving devices may include the first light-receiving device PD1. The first light-emitting device ED1, the second light-emitting device ED2 (FIG. 5), and the third light-emitting device ED3 (FIG. 5) may emit light of different colors. For example, the first light-emitting device ED1 may emit green light, the second light-emitting device ED2 (FIG. 5) may emit red light, and the third light-emitting device ED3 (FIG. 5) may emit blue light. The red light may be light of a wavelength band of about 580 nm to about 780 nm, the blue light may be light of a wavelength band of about 380 nm to about 495 nm, and the green light may be light of a wavelength band of about 495 nm to about 580 nm. The first light-receiving device PD1 may sense an object by detecting light emitted from the first light-emitting device ED1, the second light-emitting device ED2 (FIG. 5), and the third light-emitting device ED3 (FIG. 5) and reflected by the object.

Each of the light-emitting devices may include a pixel electrode, an opposite electrode, and an emission layer arranged therebetween, and each of the light-receiving devices may include a sensing electrode, an opposite electrode, and an activation layer arranged therebetween. Accordingly, the first light-emitting device ED1 may include a first pixel electrode 210-1, and the first light-receiving device PD1 may include a first sensing electrode 210-2. The first pixel electrode 210-1 and the first sensing electrode 210-2 may be arranged apart from each other on the substrate 100. Throughout the specification, the expression “on a plane” refers to a plane viewed from a direction perpendicular to the substrate 100. In other words, the expression “A and B apart from each other on a plane” refers to A and B apart from each other when viewed in a direction perpendicular to the substrate 100.

A bank layer 109 may be disposed above the first pixel electrode 210-1 of the first light-emitting device ED1 and the first sensing electrode 210-2 of the first light-receiving device PD1 and may cover an edge of each of the first pixel electrode 210-1 and the first sensing electrode 210-2. In other words, the bank layer 109 may include a first lower opening LOP1 exposing a central portion of the first pixel electrode 210-1 and a second lower opening LOP2 exposing a central portion of the first sensing electrode 210-2.

Although not shown in FIG. 7, an emission layer emitting light may be arranged in the first lower opening LOP1 of the bank layer 109, and an activation layer detecting light may be arranged in the second lower opening LOP2 of the bank layer 109. An opposite electrode may be disposed on the emission layer and the activation layer. A structure of a stack of the pixel electrode, the emission layer, and the opposite electrode as described above may form one light-emitting device. In addition, a structure of a stack of the sensing electrode, the activation layer, and the opposite electrode as described above may form one light-receiving device. In other words, one opening of the bank layer 109 may correspond to one light-emitting device and define one emission region. Alternatively, one opening of the bank layer 109 may correspond to one light-receiving device and define one sensing region.

For example, an emission layer emitting green light may be arranged in the first lower opening LOP1 to define a first emission region EA1 in the first lower opening LOP1. Similarly, an activation layer detecting light may be arranged in the second lower opening LOP2, and the second lower opening LOP2 may define a first sensing region SA1. Accordingly, the size of the area of the first lower opening LOP1 may be equal to the size of the area of the first emission region EA1. Likewise, the size of the area of the second lower opening LOP2 may be equal to the size of the area of the first sensing region SA1. For example, the size of a width W1 of the first lower opening LOP1 may be equal to the size of the width of the first emission region EA1, and the size of a width W1′ of the second lower opening LOP2 may be equal to the size of the width of the first sensing region SA1.

Each of the first lower opening LOP1 and the second lower opening LOP2 may have a polygonal shape when viewed in a direction (z-axis direction) perpendicular to the substrate 100. In other words, each of the first emission region EA1 and the first sensing region SA1 may have a polygonal shape when viewed in a direction (z-axis direction) perpendicular to the substrate 100. FIG. 7 illustrates that each of the first emission region EA1 and the first sensing region SA1 has a quadrangular shape when viewed in a direction (z-axis direction) perpendicular to the substrate 100. However, the disclosure is not limited thereto. For example, each of the first emission region EA1 and the first sensing region SA1 may have a circular shape or an elliptical shape when viewed in a direction (z-axis direction) perpendicular to the substrate 100.

The first functional layer 410 of the optical functional layer OU may be disposed on the bank layer 109. The first functional layer 410 may include middle openings respectively corresponding to a plurality of emission regions and a plurality of light-receiving regions. Specifically, the first functional layer 410 may include a first middle opening MOP1 corresponding to the first emission region EA1 and overlapping the first lower opening LOP1 and a second middle opening MOP2 corresponding to the first sensing region SA1 and overlapping the second lower opening LOP2. Although not shown in FIG. 7, the first middle opening MOP1 and the second middle opening MOP2 of the first functional layer 410 may be filled with the second functional layer 420 of the optical functional layer OU.

The size of the area of the first middle opening MOP1 may be greater than the size of the area of the first lower opening LOP1. This is to improve luminescence efficiency of light emitted from the first emission region EA1. Likewise, the size of the area of the second middle opening MOP2 may be greater than the size of the area of the second lower opening LOP2. This is to improve light-receiving efficiency of light reflected by an object and entering the first sensing region SA1. For example, the size of a width W2 of the first middle opening MOP1 may be greater than the size of the width W1 of the first lower opening LOP1, and the size of a width W2′ of the second middle opening MOP2 may be greater than the size of the width W1′ of the second lower opening LOP2.

Accordingly, when viewed in a direction perpendicular to the substrate 100, the bank layer 109 may be arranged to further protrude toward the first emission region EA1, compared to the first functional layer 410. Likewise, the bank layer 109 may be arranged to further protrude toward the first sensing region SA1, compared to the first functional layer 410. Specifically, the bank layer 109 may include a portion which further protrudes toward the first emission region EA1 by a first distance DI, compared to the first functional layer 410, and may include a portion which further protrudes toward the first sensing region SA1 by a first distance DI′, compared to the first functional layer 410. In an embodiment, the first distances DI and DI′ may each have a length of about 0.3 μm to 0.5 μm.

The light-blocking layer BM of the color filter layer CU may be disposed on the optical functional layer OU. The light-blocking layer BM may include upper openings respectively corresponding to the plurality of emission regions and the plurality of light-receiving regions. Specifically, the light-blocking layer BM may include a first upper opening UOP1 corresponding to the first emission region EA1 and overlapping the first lower opening LOP1 and a second upper opening UOP2 corresponding to the first sensing region SA1 and overlapping the second lower opening LOP2. In other words, the first upper opening UOP1 may overlap the first lower opening LOP1 and the first middle opening MOP1, and the second upper opening UOP2 may overlap the second lower opening LOP2 and the second middle opening MOP2. Although not shown in FIG. 7, the first upper opening UOP1 and the second upper opening UOP2 of the light-blocking layer BM may be filled with the color filter CF of the color filter layer CU.

The size of the area of the first upper opening UOP1 may be greater than the size of area of each of the first lower opening LOP1 and the first middle opening MOP1. This is to improve efficiency of light emitted from the first emission region EA1. Likewise, the size of the area of the second upper opening UOP2 may be greater than the size of the area of each of the second lower opening LOP2 and the second middle opening MOP2. This is to improve light-receiving efficiency of light reflected by an object and entering the first sensing region SA1. For example, the size of a width W3 of the first upper opening UOP1 may be greater than the size of the width W1 of the first lower opening LOP1 and the size of the width W2 of the first middle opening MOP1. The size of a width W3′ of the second upper opening UOP2 may be greater than the size of the width W1′ of the second lower opening LOP2 and the width W2′ of the second middle opening MOP2. Accordingly, when viewed in a direction perpendicular to the substrate 100, the first functional layer 410 may be arranged to further protrude toward each of the first emission region EA1 and the first sensing region SA1, compared to the light-blocking layer BM.

Next, referring to FIG. 8, the display apparatus 1 may include the substrate 100, a thin-film transistor TFT, the first light-emitting device ED1, the first light-receiving device PD1, a thin-film encapsulation layer 300, the input sensing layer TU, an optical functional layer OU, a color filter layer CU, and the cover window CW.

The substrate 100 may include glass or polymer resin. The substrate 100 may include polymer resin, such as polyethersulfone, polyacrylate, polyetherimide, polyethylene naphthalate, polyethylene terephthalate, polyphenylene sulfide, polyarylate, polyimide, polycarbonate, or cellulose acetate propionate. The substrate 100 including polymer resin may be flexible, rollable, or bendable. The substrate 100 may have a multilayer structure including a layer including the polymer resin and an inorganic layer (not shown).

A buffer layer 101 may be disposed on the substrate 100, and thus, may reduce or block penetration of foreign substances, moisture, or external air from a lower portion of the substrate 100 and provide a flat surface on the substrate 100. The buffer layer 101 may include an inorganic material such as an oxide or a nitride, an organic material, or an organic/inorganic composite, and may formed as a single-layered or multilayer structure of the inorganic material and the organic material. In an embodiment, the buffer layer 101 may include silicon oxide (SiO_{X}), silicon nitride (SiN_{X}) or/and silicon oxynitride (SiON).

The thin-film transistor TFT may be disposed on the buffer layer 101. The thin-film transistor TFT may include a semiconductor layer Act, a gate electrode GE, a source electrode SE, and a drain electrode DE. FIG. 8 illustrates a top gate type in which the gate electrode GE is disposed on the semiconductor layer Act with a gate insulating layer 103 therebetween, but the disclosure is not limited thereto. For example, the thin-film transistor TFT may be a bottom gate type.

The semiconductor layer Act may be disposed on the buffer layer 101. The semiconductor layer Act may include a channel region, and a source region and a drain region, which are respectively at both sides of the channel region and are doped with impurities. In this case, the impurities may include N-type impurities or P-type impurities. The semiconductor layer Act may include amorphous silicon or polysilicon. In an embodiment, the semiconductor layer Act may include an oxide of at least one material selected from the group including indium (In), gallium (Ga), stannum (Sn), zirconium (Zr), vanadium (V), hafnium (Hf), cadmium (Cd), germanium (Ge), chromium (Cr), titanium (Ti), aluminum (Al), cesium (Cs), cerium (Ce), and zinc (Zn). In addition, the semiconductor layer Act may include a Zn oxide, an In—Zn oxide, or a Ga—In—Zn oxide, as a Zn-oxide-based material. In addition, the semiconductor layer Act may be an In—Ga—Zn—O (IGZO), In—Sn—Zn—O (ITZO), or In—Ga—Sn—Zn—O (IGTZO) semiconductor containing a metal such as indium (In), gallium (Ga), or stannum (Sn) in ZnO.

The gate electrode GE may be disposed on the semiconductor layer Act such that at least a portion thereof overlaps the semiconductor layer Act. Specifically, the gate electrode GE may overlap the channel region of the semiconductor layer Act. The gate electrode GE may include various conductive materials including molybdenum (Mo), aluminum (Al), copper (Cu), titanium (Ti), and the like and may have various layer structures. For example, the gate electrode GE may include a Mo layer and an Al layer or may have a multilayer structure of Mo layer/Al layer/Mo layer.

The gate insulating layer 103 may be arranged between the semiconductor layer Act and the gate electrode GE. The gate insulating layer 103 may include silicon oxide (SiO_{X}), silicon nitride (SiN_{X}), or/and silicon oxynitride (SiON) and may be a single layer or a multilayer.

The source electrode SE and the drain electrode DE may be connected to the source region and the drain region of the semiconductor layer Act via a contact hole. The source electrode SE and the drain electrode DE may each include various conductive materials including molybdenum (Mo), aluminum (Al), copper (Cu), titanium (Ti), and the like and may each have various layer structures. For example, the source electrode SE and the drain electrode DE may each include a Ti layer and an Al layer or may have a multilayer structure of Ti layer/Al layer/Ti layer. In addition, the source electrode SE and the drain electrode DE may have a multilayer structure including an ITO layer covering a metal material.

An interlayer insulating layer 105 may be arranged between the gate electrode GE and the source electrode SE and between the gate electrode GE and the drain electrode DE. The interlayer insulating layer 105 may include silicon oxide (SiO_{X}), silicon nitride (SiN_{X}), or/and silicon oxynitride (SiON) and may be a single layer or a multilayer.

The thin-film transistor TFT may be covered with an organic insulating layer 107. For example, the organic insulating layer 107 may cover the source electrode SE and the drain electrode DE. The organic insulating layer 107 is a planarization insulating layer and may include a substantially flat upper surface. The organic insulating layer 107 may include an organic insulating material such as a general-purpose polymer such as polymethyl methacrylate (PMMA) or polystyrene (PS), a polymer derivative having a phenolic group, an acrylic polymer, an imide-based polymer, an aryl ether-based polymer, an amide-based polymer, a fluorine-based polymer, a p-xylene-based polymer, a vinyl alcohol-based polymer, and a blend thereof. In an embodiment, the organic insulating layer 107 may include polyimide.

The first pixel electrode 210-1, the first sensing electrode 210-2, and the bank layer 109 may be disposed on the organic insulating layer 107. The bank layer 109 may cover the edge of each of the first pixel electrode 210-1 and the first sensing electrode 210-2 and may be disposed on the organic insulating layer 107.

The first lower opening LOP1 exposing at least the central portion of the first pixel electrode 210-1 and the second lower opening LOP2 exposing at least the central portion of the first sensing electrode 210-2 may be arranged in the bank layer 109. Accordingly, the first lower opening LOP1 may define the first emission region EA1, and the second lower opening LOP2 may define the first sensing region SA1.

The bank layer 109 may prevent an arc from occurring at the edge of the first pixel electrode 210-1 by increasing a distance between the edge of the first pixel electrode 210-1 and an opposite electrode 230. In addition, the bank layer 109 may prevent an arc from occurring at the edge of the first sensing electrode 210-2 by increasing a distance between the edge of the first sensing electrode 210-2 and the opposite electrode 230.

The bank layer 109 may include an organic insulating material such as polyimide, polyamide, acrylic resin, benzocyclobutene, hexamethyldisiloxane (HMDSO), and phenolic resin, and may be formed via a method such as spin coating.

An emission layer 222-1 may be arranged in the first lower opening LOP1 arranged in the bank layer 109. The emission layer 222-1 may include an organic material including a fluorescent or phosphorescent material emitting red light, green light, blue light, or white light. The emission layer 222-1 may be an organic emission layer including a low-molecular-weight organic material or a polymer organic material. For example, the emission layer 222-1 may include, as the organic emission layer, copper phthalocyanine, tris-8-hydroxyquinoline aluminum, a poly-phenylenevinylene (PPV)-based material, or a polyfluorene-based material.

In an embodiment, the emission layer 222-1 may include a host material and a dopant material. The dopant material is a material emitting light of a specific color and may include a luminescent material. The luminescent material may include at least one of a phosphorescent dopant, a fluorescent dopant, and a quantum dot. The host material is a main material of the emission layer 222-1 and is a material which helps the dopant material to emit light.

An activation layer 222-2 may be arranged in the second lower opening LOP2 arranged in the bank layer 109. The activation layer 222-2 may include a p-type organic semiconductor and an n-type organic semiconductor. In this case, the p-type organic semiconductor may act as an electron donor, and the n-type organic semiconductor may act as an electron acceptor.

In an embodiment, the activation layer 222-2 may be a mixed layer in which the p-type organic semiconductor and the n-type organic semiconductor are mixed. In this case, the activation layer 222-2 may be formed by co-depositing the p-type organic semiconductor and the n-type organic semiconductor. When the activation layer 222-2 is a mixed layer, excitons may be generated within a diffusion length from a donor-acceptor interface.

In an embodiment, the p-type organic semiconductor may be a compound which acts as an electron donor for supplying electrons. For example, the p-type organic semiconductor may include, but is not limited to, boron subphthalocyanine chloride (SubPc), copper (II) phthalocyanine (CuPc), tetraphenyldibenzoferiflanthene (DBP), or any combination thereof.

In an embodiment, the n-type organic semiconductor may be a compound which acts as an electron acceptor for accepting electrons. For example, the n-type organic semiconductor may include, but is not limited to, C60 fullerene, C70 fullerene, or any combination thereof.

The opposite electrode 230 may be disposed on the emission layer 222-1 and the activation layer 222-2. The opposite electrode 230 disposed on the emission layer 222-1 and the activation layer 222-2 may be integrally formed. The opposite electrode 230 may be a light-transmissive electrode or a reflective electrode. In an embodiment, the opposite electrode 230 may be a transparent or semi-transparent electrode and may include a metal thin film having a small work function, the metal thin film including Li, Ca, LiF/Ca, LiF/Al, Al, Ag, Mg, and a compound thereof. In addition, the opposite electrode 230 may further include a transparent conductive oxide (TCO) film such as ITO, IZO, ZnO, or In₂O₃, in addition to the metal thin film.

A first common layer 221 may be arranged between the first pixel electrode 210-1 and the emission layer 222-1 and between the first sensing electrode 210-2 and the activation layer 222-2, and a second common layer 223 may be arranged between the emission layer 222-1 and the opposite electrode 230 and between the activation layer 222-2 and the opposite electrode 230.

In an embodiment, a hole transport region may be defined between the first pixel electrode 210-1 and the emission layer 222-1 and between the first sensing electrode 210-2 and the activation layer 222-2, and an electron transport region may be defined between the emission layer 222-1 and the opposite electrode 230 and between the activation layer 222-2 and the opposite electrode 230.

The hole transport region may include a single-layered structure or a multilayer structure. For example, the first common layer 221 may be arranged in the hole transport region. In an embodiment, the first common layer 221 may include at least one of a hole injection layer (HIL), a hole transport layer (HTL), and an electron blocking layer (EBL). A bank 111 may be disposed on the bank layer 109 but under the first common layer 221 between the first emission region EA1 and the first sensing region SA1, so as to avoid light in the first emission region EA1 and the first sensing region SA1 from interfering with each other avoid.

For example, the first common layer 221 may have a single-layered structure or may have a multilayer structure. When the first common layer 221 includes a multilayer structure, the first common layer 221 may include an HIL and an HTL sequentially stacked from the first pixel electrode 210-1, may include an HIL and an EBL, may include an HTL and an EBL, or may include an HIL, an HTL, an EBL. However, the disclosure is not limited thereto.

In an embodiment, the first common layer 221 may include at least one selected from among m-MTDATA, TDATA, 2-TNATA, NPB(NPD), β-NPB, TPD, spiro-TPD, spiro-NPB, methylated NPB, TAPC, HMTPD, 4,4′,4-tris(N-carbazolyl)triphenylamine (TCTA), polyaniline/dodecylbenzenesulfonic acid (PANI/DBSA), polyaniline/camphor sulfonic acid (PANI/CSA), poly(3,4-cthylenedioxythiophenc)/poly(4-styrenesulfonate) (PEDOT/PSS), and polyaniline/poly(4-styrenesulfonate) (PANI/PSS).

The electron transport region may include a single-layered structure or a multilayer structure. For example, the second common layer 223 may be arranged in the electron transport region. In an embodiment, the second common layer 223 may include at least one of an electron injection layer (EIL), an electron transport layer (ETL), and a hole blocking layer (HBL).

For example, the second common layer 223 may have a single-layered structure or may have a multilayer structure. When the second common layer 223 includes a multilayer structure, the second common layer 223 may include an ETL and an EIL sequentially stacked from the emission layer 222-1, may include an HBL and an EIL, may include an HBL and an ETL, or may include an HBL, an ETL, and an EIL. However, the disclosure is not limited thereto.

In an embodiment, the second common layer 223 may include at least one compound selected from among 2,9-dimethyl-4,7-diphenyl-1,10-phenanthroline (BCP), 4,7-diphenyl-1,10-phenanthroline (Bphen), Alq3, BAlq, 3-(biphenyl-4-yl)-5-(4-tert-butylphenyl)-4-phenyl-4H-1,2,4-triazole (TAZ), and NTAZ.

The first light-emitting device ED1 may include the first pixel electrode 210-1, the first common layer 221, the emission layer 222-1, the second common layer 223, and the opposite electrode 230, which are sequentially stacked. The first light-receiving device PD1 may include the first sensing electrode 210-2, the first common layer 221, the activation layer 222-2, the second common layer 223, and the opposite electrode 230, which are sequentially stacked.

The thin-film transistor TFT may be arranged between the substrate 100 and the first light-emitting device ED1. The thin-film transistor TFT may be electrically connected to the first light-emitting device ED1 to drive the first light-emitting device ED1. For example, one of the source electrode SE and the drain electrode DE of the thin-film transistor TFT may be electrically connected with the first pixel electrode 210-1 of the first light-emitting device ED1.

The thin-film transistor TFT may be arranged between the substrate 100 and the first light-receiving device PD1. The thin-film transistor TFT may be electrically connected to the first light-receiving device PD1 to drive the first light-receiving device PD1. For example, one of the source electrode SE and the drain electrode DE of the thin-film transistor TFT may be electrically connected with the first sensing electrode 210-2 of the first light-receiving device PD1.

The activation layer 222-2 may generate excitons by receiving light from the outside, and then separate the generated excitons into holes and electrons. When (+) potential is applied to the first sensing electrode 210-2 and (−) potential is applied to the opposite electrode 230, the holes obtained by the separation in the activation layer 222-2 may move toward the opposite electrode 230, and the electrons obtained by the separation in the activation layer 222-2 may move toward the first sensing electrode 210-2. Therefore, a photocurrent may be formed in a direction from the first sensing electrode 210-2 toward the opposite electrode 230.

When a bias is applied between the first sensing electrode 210-2 and the opposite electrode 230, a dark current may flow through the first light-receiving device PD1. In addition, when light is incident on the first light-receiving device PD1, a photocurrent may flow through the first light-receiving device PD1. In an embodiment, the first light-receiving device PD1 may detect the amount of light from a ratio of the photocurrent to the dark current.

An auxiliary layer 240 may be disposed above the first light-emitting device ED1 and the first light-receiving device PD1. For example, the auxiliary layer 240 may be disposed on the opposite electrode 230. The auxiliary layer 240 may lower an energy barrier of holes moving in a direction of an HTL and an anode to facilitate movement of the holes. The auxiliary layer 240 may be formed of, for example, a fluorene-based compound, a carbazole-based compound, a diarylamine-based compound, a triarylamine-based compound, a dibenzofuran-based compound, a dibenzothiophene-based compound, a dibenzosilol-based compound, or any combination thereof.

The thin-film encapsulation layer TFE may be disposed above the first light-emitting device ED1 and the first light-receiving device PD1. For example, the thin-film encapsulation layer TFE may be disposed on the auxiliary layer 240. The thin-film encapsulation layer TFE may include at least one inorganic encapsulation layer and at least one organic encapsulation layer, and in an embodiment, FIG. 8 illustrates that the thin-film encapsulation layer TFE includes a first inorganic encapsulation layer 310, an organic encapsulation layer 320, and a second inorganic encapsulation layer 330.

The first inorganic encapsulation layer 310 and the second inorganic encapsulation layer 330 may include at least one inorganic material among aluminum oxide, titanium oxide, tantalum oxide, hafnium oxide, zinc oxide, silicon oxide, silicon nitride, and silicon oxynitride. The organic encapsulation layer 320 may include a polymer-based material. The polymer-based material may include acrylic resin, epoxy-based resin, polyimide, and polyethylene. In an embodiment, the organic encapsulation layer 320 may include acrylate. The organic encapsulation layer 320 may be formed by curing a monomer or applying a polymer. The organic encapsulation layer 320 may have transparency.

The input sensing layer TU may be disposed on the thin-film encapsulation layer TFE. The input sensing layer TU may obtain coordinate information according to an external input, for example, a touch event. The input sensing layer TU includes the first inorganic insulating layer IL1, the first conductive layer MTL1 on the first inorganic insulating layer IL1, the second inorganic insulating layer IL2 on the first conductive layer MTL1, and the second conductive layer MTL2 on the second inorganic insulating layer IL2. In addition, the first conductive layer MTL1 and the second conductive layer MTL2 may correspond to a first sensor portion SP1 of FIG. 6.

As described above, the first sensor portions SP1 may not overlap an emission region and may overlap a non-emission region. The first conductive layer MTL1 and the second conductive layer MTL2 may be arranged not to overlap the first emission region EA1 or the first sensing region SA1. In other words, the first conductive layer MTL1 and the second conductive layer MTL2 may be arranged to overlap the bank layer 109 or the first functional layer 410. Although not shown, in some regions, the first conductive layer MTL1 and the second conductive layer MTL2 may be electrically connected to each other via a contact hole defined in the second inorganic insulating layer IL2.

The optical functional layer OU may be disposed on the input sensing layer TU. The optical functional layer OU may control a path of light emitted from the first emission region EA1 and a path of light entering the first sensing region SA1. For example, the optical functional layer OU may change a path of light which travels in a lateral direction (for example, a direction other than a third direction (z direction)) among light emitted from the emission layer 222-1 of the first light-emitting device ED1, and allow the light to travel substantially forward in the third direction (z direction). In addition, the optical functional layer OU may change a path of light which travels in the lateral direction (for example, a direction other than the third direction (z direction)) among light reflected by an object and entering the display apparatus, and allow the light to substantially travel in the third direction (z direction).

The optical functional layer OU may include the first functional layer 410 covering the second conductive layer MTL2 and disposed on the second inorganic insulating layer IL2 and the second functional layer 420 disposed on the first functional layer 410. In an embodiment, a height H1 of the optical functional layer OU including the first functional layer 410 and the second functional layer 420 may be about 1.5 μm to about 5 μm, based on a thickness direction of the substrate 100. In an embodiment, as shown in FIG. 7, the height of the first functional layer 410 and the height of the second functional layer 420 may be equal to each other.

The first functional layer 410 may include the first middle opening MOP1 to correspond to the first emission region EA1 and the second middle opening MOP2 to correspond to the first sensing region SA1. The first middle opening MOP1 may overlap the first lower opening LOP1, and the second middle opening MOP2 may overlap the second lower opening LOP2. The width W2 of the first middle opening MOP1 may be greater than the width W1 of the first lower opening LOP1. This may mean that the area of the first middle opening MOP1 is greater than the area of the first emission region EA1 on a plane. Likewise, the width W2′ of the second middle opening MOP2 may also be greater than the width W1′ of the second lower opening LOP2. This is to increase luminescence efficiency and light-receiving efficiency by strengthening straightness of light because the first middle opening MOP1 is located in an extraction direction of light emitted from the first emission region EA1 and extracted to the outside and the second middle opening MOP2 is located in an entering direction of light entering the first sensing region SA1 from the outside.

Meanwhile, the second functional layer 420 having a refractive index greater than a refractive index of the first functional layer 410 may be further disposed on the first functional layer 410 to further increase the luminescence efficiency and the light-receiving efficiency. The second functional layer 420 may be a planarization layer filling openings of the first functional layer 410. The second functional layer 420 may at least partially fill the first middle opening MOP1 and the second middle opening MOP2. A portion of the second functional layer 420 may be in direct contact with an upper surface of the second inorganic insulating layer IL2 via the first middle opening MOP1 and the second middle opening MOP2.

The first functional layer 410 may include an organic insulating material having a first refractive index, and the second functional layer 420 may include an organic insulating material having a second refractive index. In an embodiment, a difference between the second refractive index of the second functional layer 420 and the first refractive index of the first functional layer 410 may be about 0.05 to about 0.3 As described above, as the second functional layer 420 has a refractive index greater than that of the first functional layer 410, total reflection may occur at an interface between the first functional layer 410 and the second functional layer 420 in the first emission region EA1 to increase luminescence efficiency, and refraction may occur at the interface between the first functional layer 410 and the second functional layer 420 in the first sensing region SA1 to increase light-receiving efficiency.

Specifically, the first refractive index of the first functional layer 410 may be about 1.3 to about 1.6. In an embodiment, the first refractive index of the first functional layer 410 may be about 1.4 to about 1.55. The first functional layer 410 may include, for example, (ethyl) hexyl acrylate, pentafluoropropyl acrylate, poly(ethylene glycol) dimethacrylate, or ethylene glycol dimethacrylate. In an embodiment, the first functional layer 410 may include an acrylic organic material having a refractive index of about 1.5. In addition, the first functional layer 410 may be formed of a material forming the organic encapsulation layer 320 of the thin-film encapsulation layer TFE. In an embodiment, the first functional layer 410 may include an epoxy-based organic material and, in some cases, may also include a photocurable material.

The second refractive index of the second functional layer 420 may be about 1.6 to about 1.85. The second functional layer 420 may include, for example, polydiarylsiloxane, methyltrimethoxysilane, or tetramethoxysilane. In an embodiment, the second functional layer 420 may include an acrylic or siloxane-based organic material having a refractive index of about 1.6. In some embodiments, the second functional layer 420 may include dispersed particles for high refractive index. Metal oxide particles, for example, zinc oxide (ZnOₓ), titanium oxide (TiO₂), zirconium oxide (ZrO₂), or barium titanate (BaTiO₃), may be dispersed in the second functional layer 420.

Meanwhile, a side surface of the first functional layer 410 facing the first middle opening MOP1 may include a forward tapered slope, and a side surface of the first functional layer 410 facing the second middle opening MOP2 may include a forward tapered slope. In other words, a first angle θ1 between the side surface of the first functional layer 410 facing the first middle opening MOP1 and a lower surface of the first functional layer 410 may be an acute angle, and a second angle θ2 between the side surface of the first functional layer 410 facing the second middle opening MOP2 and the lower surface of the first functional layer 410 may also be an acute angle.

In this case, the first angle θ1 and the second angle θ2 of the first functional layer 410 may be different from each other. Specifically, the first angle θ1 which is an inclination angle of the side surface of the first functional layer 410 facing the first emission region EA1 may be greater than the second angle θ2 which is an inclination angle of the side surface of the first functional layer 410 facing the first sensing region SA1. In an embodiment, the first angle θ1 of the first functional layer 410 may be about 70° to about 90°, and the second angle θ2 may be about 30° to about 60°.

Specifically, as shown in FIG. 9, light emitted from the emission layer 222-1 may include first light L1 which is obliquely incident on the side surface of the first functional layer 410 and third light L3 which passes through the second functional layer 420 and is extracted in the substantially third direction (z direction) without changing its direction. Among them, the first light L1 incident on the inclined side surface of the first functional layer 410 may be totally reflected at the interface between the first functional layer 410 and the second functional layer 420 to change its path, and totally reflected second light L2 may be extracted in the substantially third direction (z direction). In other words, the total reflection at the interface between the first functional layer 410 having the first refractive index and the second functional layer 420 having the second refractive index greater than the first refractive index may increase front light extraction efficiency, thereby increasing front visibility.

Especially, an incident angle of the first light L1 incident on the first functional layer 410 needs to be greater than a critical angle in order for total reflection of the first light L1 incident on the first functional layer 410 to occur at the interface between the first functional layer 410 and the second functional layer 420. To this end, the first angle θ1 of the first functional layer 410 facing the first emission region EA1 may be about 70° to about 90°.

In contrast, as shown in FIG. 9, light reflected by an object and entering the display apparatus 1 may include fifth light L5 which is obliquely incident on the side surface of the first functional layer 410 and fourth light LA which passes through the second functional layer 420 and is extracted in the third direction (z direction) without changing its direction. Among them, the fifth light L5 incident on the inclined side surface of the first functional layer 410 may be refracted at the interface between the first functional layer 410 and the second functional layer 420 to change its path, and refracted sixth light L6 may be extracted in the substantially the third direction (2 direction) and may enter the activation layer 222-2. In other words, the refraction at the interface between the first functional layer 410 having the first refractive index and the second functional layer 420 having the second refractive index greater than the first refractive index may increase light-receiving efficiency, thereby increasing the amount of light entering the first light-receiving device PD1.

Especially, the amount of light refracted at the interface between the first functional layer 410 and the second functional layer 420 and entering the first light-receiving device PD1 may increase as the area of the interface between the first functional layer 410 and the second functional layer 420 increases. In other words, as the area of the side surface of the first functional layer 410 facing the second middle opening MOP2 increases, the amount of light which is obliquely incident on the first functional layer 410 increases, and thus, more light may be refracted and thus may enter the first light-receiving device PD1. In this case, in order to increase the area of the side surface of the first functional layer 410 facing the second middle opening MOP2, there is a method of increasing the thickness of the first functional layer 410, but this increases the thickness of the display apparatus, and thus, there may be process limitations. Accordingly, in the display apparatus according to an embodiment, the second angle θ2 which is an inclination angle of the side surface of the first functional layer 410 facing the first sensing region SA1 may be smaller than the first angle θ1 to expand the side surface of the first functional layer 410 facing the first sensing region SA1. To this end, the second angle θ2 of the first functional layer 410 may be about 30° to about 60°.

In this case, a slit may be used to differently form the first angle θ1 and the second angle θ2 of the first functional layer 410. Specifically, first, a preliminary layer may be formed on the second inorganic insulating layer IL2 by using a material for forming the first functional layer 410, and the preliminary layer may be exposed to light by using a mask. In this case, the preliminary layer may include a photoresist material, and a portion of the preliminary layer, which is not exposed to light, may be removed in a later development process.

In this case, the mask may include a slit having an area overlapping an upper surface of the first functional layer 410, in a region in which the mask and the upper surface of the first functional layer 410 overlap each other. In addition, the mask may include, in a region in which the side surface of the first functional layer 410 facing the first sensing region SA1, the side surface having a low slope, is to be formed, a slit having an area smaller than the corresponding region, and may not include a slit in other regions. As such, when the preliminary layer is exposed to light by using a mask including a slit in a region in which the mask and the side surface of the first functional layer 410 surrounding the first light-receiving device PD1 overlap each other, and then developed, the first functional layer 410 having both side surfaces having different inclination angles may be formed.

As a result, the display apparatus 1 according to an embodiment may have improved luminescence efficiency and improved light-receiving efficiency due to the structure and the difference in the refractive indices of the optical functional layer OU. In addition, when the amount of light entering the first light-receiving device PD1 is increased, a deviation between a correct signal and a noise is increased, such that sensor sensitivity and sensor reliability can be improved.

Referring back to FIG. 8, the color filter layer CU may be disposed on the optical functional layer OU. The color filter layer CU may include the light-blocking layer BM and a color filter CF. The color filter CF may include a first color filter CF1, and a second color filter CF2.

The light-blocking layer BM may be disposed on the optical functional layer OU. The light-blocking layer BM includes a light-blocking material, and thus, the light-blocking layer BM may at least partially absorb internally reflected light. The light-blocking material may include resin or paste including carbon black, carbon nanotubes, or black dye, or metal particles. The metal particles may be, for example, nickel, aluminum, molybdenum, or an alloy thereof. In addition, the light-blocking material may include metal oxide particles such as chromium oxide or metal nitride particles such as chromium nitride. The light-blocking layer BM may reduce reflection of external light by ensuring that the light-blocking layer BM includes the light-blocking material. As necessary, the light-blocking layer BM may include a material same as that of the bank layer 109 disposed thereunder. However, the disclosure is not limited thereto, and the light-blocking layer BM may include a material different from that of the bank layer 109.

The light-blocking layer BM may include the first upper opening UOP1 corresponding to the first emission region EA1 and the second upper opening UOP2 corresponding to the first sensing region SA1. In other words, the first upper opening UOP1 may overlap the first lower opening LOP1 and the first middle opening MOP1, and the second upper opening UOP2 may overlap the second lower opening LOP2 and the second middle opening MOP2. The area of the first upper opening UOP1 may be greater than the area of each of the first lower opening LOP1 and the first middle opening MOP1, and the area of the second upper opening UOP2 may be greater than the area of each of the second lower opening LOP2 and the second middle opening MOP2. The light-blocking layer BM includes the first and second upper openings UOP1 and UOP2, and thus may have a lattice shape or a mesh shape. In addition, the shapes of the first upper opening UOP1 and the second upper opening UOP2 of the light-blocking layer BM may be the same as the shapes of the first lower opening LOP1 and the second lower opening LOP2 of the bank layer 109, respectively.

The first color filter CF1 and the second color filter CF2 may be disposed on the light-blocking layer BM. The first color filter CF1 and the second color filter CF2 may allow only light having a wavelength belonging to a specific band to pass therethrough. The first color filter CF1 may fill the first upper opening UOP1 of the light-blocking layer BM, and the second color filter CF2 may fill the second upper opening UOP2 of the light-blocking layer BM.

In the case of the display apparatus 1, the color filter CF is disposed above each pixel to reduce reflection of external light. For example, in the case of a pixel emitting red light, a red color filter allowing only red light to pass therethrough may be disposed above the pixel, and in the case of a pixel emitting blue light, a blue color filter allowing only blue light to pass therethrough may be disposed above the pixel. Accordingly, when external light, which is white light, is incident on, for example, a red color filter, blue light and green light are absorbed by the red color filter, and only red light passes through the red color filter, is reflected by a pixel electrode, passes through the red color filter again, and then is emitted to the outside. Therefore, in the case of a display apparatus having a color filter, reflection of external light is reduced by approximately ⅓ compared to a case of a display apparatus having no color filter.

The first color filter CF1 may allow light emitted from the first light-emitting device ED1 to pass therethrough. For example, when the first light-emitting device ED1 emits green light, the first color filter CF1 may be a green color filter allowing green light to pass therethrough. In addition, when the first light-emitting device ED1 emits red light, the first color filter CF1 may be a red color filter allowing red light to pass therethrough.

The second color filter CF2 may allow light to pass that is the same color as the light that passes through the first color filter CF1. When the first color filter CF1 is a green color filter, the second color filter CF2 may be a green color filter. In addition, when the first color filter CF1 is a red color filter, the second color filter CF2 may be a red color filter.

The cover window CW may be disposed above the color filter layer CU. The cover window CW may include at least one of glass, sapphire, and plastic. The cover window CW may be, for example, ultra-thin glass (UTG) or colorless polyimide (CP1).

An adhesive member AD may be arranged between the cover window CW and the color filter layer CU. Therefore, the adhesive member AD may bond the cover window CW and the color filter layer CU together. The adhesive member AD may employ any general member that is well-known in the field of technology without limitation. For example, the adhesive member AD may be an optically clear adhesive (OCA) member or a pressure sensitive adhesive (PSA).

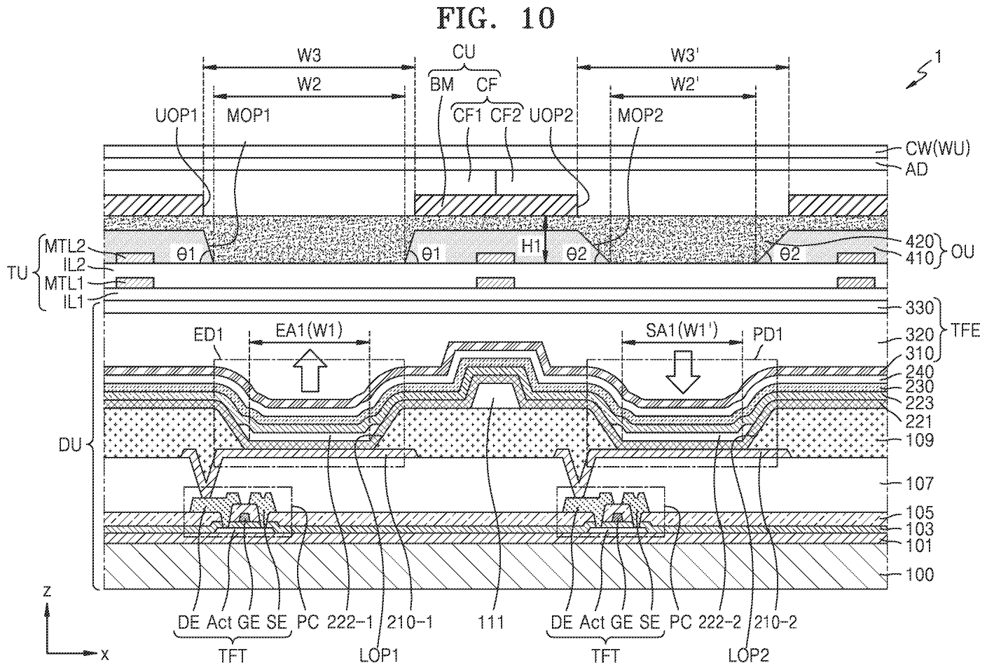

FIG. 10 is a schematic cross-sectional view of a portion of a display apparatus according to another embodiment. Referring to FIG. 10, except for the characteristics of the optical functional layer OU, other characteristics are the same as described with reference to FIGS. 7 to 9. The same reference numerals among components of FIG. 10 are substituted for those previously described with reference to FIGS. 7 to 9, and differences are mainly described in the following description.

Referring to FIG. 10, the optical functional layer OU may include the first functional layer 410 covering the second conductive layer MTL2 and disposed on the second inorganic insulating layer IL2 and the second functional layer 420 disposed on the first functional layer 410. In an embodiment, the height H1 of the optical functional layer OU including the first functional layer 410 and the second functional layer 420 may be about 1.5 μm to about 5 μm, based on a thickness direction of the substrate 100. However, in an embodiment, as shown in FIG. 10, the height of the second functional layer 420 may be greater than the height of the first functional layer 410.

Specifically, the first functional layer 410 may include the first middle opening MOP1 to correspond to the first emission region EA1 and the second middle opening MOP2 to correspond to the first sensing region SA1. the second functional layer 420 having the second refractive index greater than the first refractive index of the first functional layer 410 may fill the first middle opening MOP1 and the second middle opening MOP2.

In this case, the second functional layer 420 may be formed via an inkjet process or a photolithography process. In the case of using an inkjet process, the second functional layer 420 may be formed by directly ejecting inkjet onto the first functional layer 410. In this process, a material for forming the second functional layer 420 may not only fill the first middle opening MOP1 and the second middle opening MOP2 of the first functional layer 410, but also overflow to the upper surface of the first functional layer 410 to form a structure in which the second functional layer 420 covers the upper surface of the first functional layer 410. In other words, the second functional layer 420 may be arranged between a lower surface of the light-blocking layer BM and the first functional layer 410.

Even in the above structure, due to the difference in the refractive indices of the optical functional layer OU and the structure thereof, total reflection may occur at the interface between the first functional layer 410 and the second functional layer 420 in the first emission region EA1 to increase the amount of light directed in all directions, and refraction may occur at the interface between the first functional layer 410 and the second functional layer 420 in the first sensing region SA1 to increase the amount of light directed toward the first light-receiving device PD1. In other words, as shown in FIG. 10, even in a structure according to another embodiment, sensor sensitivity may be improved while excellent image quality is realized, by improving luminescence efficiency and light-receiving efficiency.

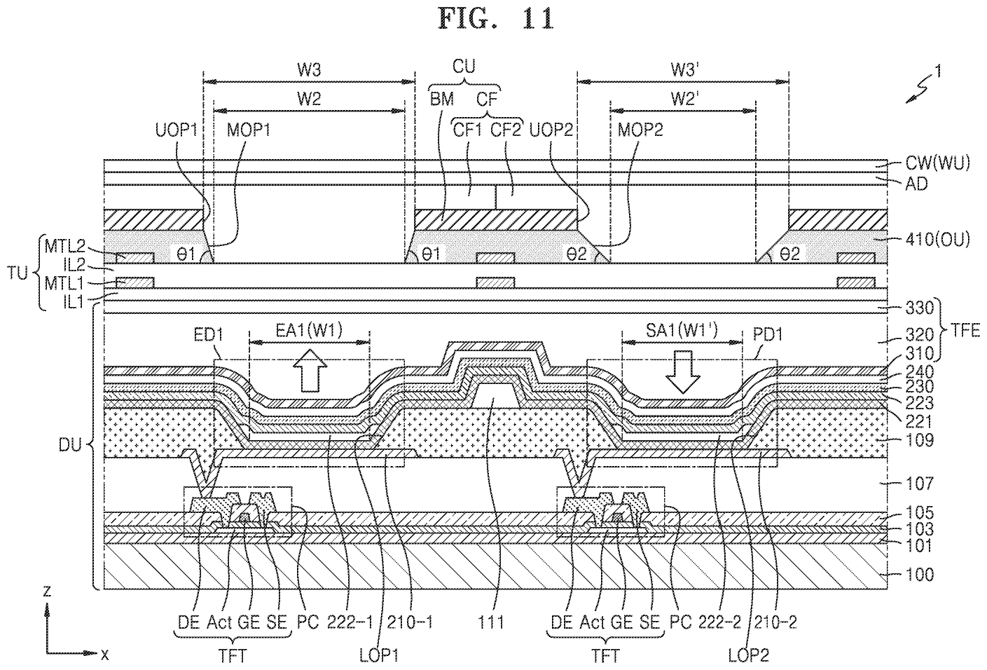

FIG. 11 is a schematic cross-sectional view of a portion of a display apparatus according to another embodiment. Referring to FIG. 11, except for the characteristics of the optical functional layer OU and the color filter layer CU, other characteristics are the same as described with reference to FIGS. 7 to 9. The same reference numerals among components of FIG. 11 are substituted for those previously described with reference to FIGS. 7 to 9, and differences are mainly described in the following description.

Referring to FIG. 11, the optical functional layer OU may include the first functional layer 410. The first functional layer 410 may cover the second conductive layer MTL2 and may be disposed on the second inorganic insulating layer IL2. The first functional layer 410 may include the first middle opening MOP1 overlapping the first emission region EA1 and the second middle opening MOP2 overlapping the first sensing region SA1.

The light-blocking layer BM of the color filter layer CU may be disposed on the first functional layer 410. The lower surface of the light-blocking layer BM may be arranged to be in direct contact with the upper surface of the first functional layer 410. The light-blocking layer BM may include the first upper opening UOP1 overlapping the first middle opening MOP1 and the second upper opening UOP2 overlapping the second middle opening MOP2.

The color filter CF may be disposed on the first functional layer 410 and the light-blocking layer BM. The first color filter CF1 may fill the first middle opening MOP1 of the first functional layer 410 and the first upper opening UOP1 of the light-blocking layer BM, and the second color filter CF2 may fill the second middle opening MOP2 of the first functional layer 410 and the second upper opening UOP2 of the light-blocking layer BM. In other words, a material of the second functional layer 420 (FIG. 8) of the optical functional layer OU, which fills the first middle opening MOP1, may include a material same as that of the first color filter CF1, which fills the first upper opening UOP1, and a material of the second functional layer 420 (FIG. 8) of the optical functional layer OU, which fills the second middle opening MOP2, may include a material same as that of the second color filter CF2, which fills the second upper opening UOP2.

In this case, the color filter CF includes a pigment to allow only light having a wavelength belonging to a specific band to pass therethrough, and thus may have a high refractive index. Specifically, a difference between a refractive index of the color filter CF and the first refractive index of the first functional layer 410 may be about 0.05 to about 0.3. Accordingly, the color filter CF may serve as the second functional layer 420 which is a high-refraction layer of the optical functional layer OU.

Therefore, even in the above structure, due to the structure of the first functional layer 410 and the difference in the refractive indices of the first functional layer 410 and the color filter CF, total reflection may occur at an interface between the first functional layer 410 and the first color filter CF1 in the first emission region EA1 to increase the amount of light directed in all directions, and refraction may occur at an interface between the first functional layer 410 and the second color filter CF2 in the first sensing region SA1 to increase the amount of light directed toward the first light-receiving device PD1. In other words, as shown in FIG. 11, even in a structure according to another embodiment, sensor sensitivity may be improved while excellent image quality is realized, by improving luminescence efficiency and light-receiving efficiency.

A display apparatus according to an embodiment may have increased luminescence efficiency to realize an image of excellent quality and simultaneously may have increased light-receiving efficiency to improve sensor sensitivity.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A display apparatus comprising:
a substrate comprising a first emission region and a first sensing region;
a first light-emitting device disposed on the substrate and corresponding to the first emission region;
a first light-receiving device disposed on the substrate and corresponding to the first sensing region; and
an optical functional layer disposed on the first light-emitting device and the first light-receiving device,
wherein the optical functional layer comprises:
a first functional layer comprising a first middle opening overlapping the first emission region and a second middle opening overlapping the first sensing region; and
a second functional layer disposed on the first functional layer and having a refractive index greater than a refractive index of the first functional layer,
the first functional layer comprises: a first angle between a first side surface facing the first middle opening and a lower surface of the first functional layer; and a second angle between a second side surface facing the second middle opening and the lower surface of the first functional layer, and
the first angle is greater than the second angle.

2. The display apparatus of claim 1, wherein the first side surface and the second side surface of the first functional layer each comprise a forward tapered slope.

3. The display apparatus of claim 1, wherein the first angle is about 70° to about 90°.

4. The display apparatus of claim 1, wherein the second angle is about 30° to about 60°.

5. The display apparatus of claim 1, wherein a difference between the refractive index of the second functional layer and the refractive index of the first functional layer is about 0.05 to about 0.3.

6. The display apparatus of claim 5, wherein the refractive index of the first functional layer is about 1.3 to about 1.6, and
the refractive index of the second functional layer is about 1.6 to about 1.85.

7. The display apparatus of claim 1, further comprising a bank layer arranged between the substrate and the optical functional layer,
wherein the bank layer comprises:
a first lower opening covering an edge of a first pixel electrode included in the first light-emitting device and exposing a central portion of the first pixel electrode; and
a second lower opening covering an edge of a first sensing electrode included in the first light-receiving device and exposing a central portion of the first sensing electrode, and
the first lower opening overlaps the first middle opening, and the second lower opening overlaps the second middle opening.

8. The display apparatus of claim 7, wherein, when viewed in a direction perpendicular to the substrate, a width of the first middle opening is greater than a width of the first lower opening, and
a width of the second middle opening is greater than a width of the second lower opening.

9. The display apparatus of claim 1, wherein a height of the optical functional layer is about 1.5 μm to about 5 μm, based on a thickness direction of the substrate.

10. The display apparatus of claim 1, wherein a height of the first functional layer and a height of the second functional layer are equal to each other, based on a thickness direction of the substrate.

11. The display apparatus of claim 1, wherein a height of the second functional layer is greater than a height of the first functional layer, based on a thickness direction of the substrate.

12. The display apparatus of claim 11, wherein the second functional layer fills the first middle opening and the second middle opening and covers an upper surface of the first functional layer.

13. The display apparatus of claim 1, further comprising:
light-blocking layer disposed on the optical functional layer and comprising a first upper opening overlapping the first middle opening and a second upper opening overlapping the second middle opening; and
a color filter comprising a first color filter filling the first upper opening and a second color filter filling the second upper opening.

14. The display apparatus of claim 13, wherein a lower surface of the light-blocking layer is in direct contact with an upper surface of the first functional layer.

15. The display apparatus of claim 13, wherein the second functional layer is arranged between a lower surface of the light-blocking layer and an upper surface of the first functional layer.

16. The display apparatus of claim 15, wherein a material of the second functional layer, which fills the first middle opening, is identical to that of the first color filter, and
a material of the second functional layer, which fills the second middle opening, is identical to that of the second color filter.

17. The display apparatus of claim 1, further comprising:
a thin-film encapsulation layer covering the first light-emitting device and the first light-receiving device; and
an input sensing layer arranged between the thin-film encapsulation layer and the optical functional layer.

18. The display apparatus of claim 17, wherein the input sensing layer comprises a conductive layer forming a touch electrode, and
the first functional layer is arranged to overlap the conductive layer.

19. A display apparatus comprising:
a first electrode and a second electrode arranged adjacent to the first electrode;
a bank layer comprising a first lower opening overlapping the first electrode and a second lower opening overlapping the second electrode;
an opposite electrode disposed on the bank layer;
a thin-film encapsulation layer disposed on the opposite electrode; and
an optical functional layer disposed on the thin-film encapsulation layer,
wherein the optical functional layer comprises:
a first functional layer comprising a first middle opening overlapping the first lower opening and a second middle opening overlapping the second lower opening; and
a second functional layer disposed on the first functional layer and having a refractive index greater than a refractive index of the first functional layer,
the first functional layer comprises: a first angle between a first side surface facing the first middle opening and a lower surface of the first functional layer; and a second angle between a second side surface facing the second middle opening and the lower surface of the first functional layer, and
the first angle is greater than the second angle.

20. The display apparatus of claim 19, wherein an emission layer emitting light is arranged in the first lower opening, and
an activation layer detecting light is arranged in the second lower opening.

21. The display apparatus of claim 19, wherein the first angle is about 70° to about 90°, and
the second angle is about 30° to about 60°.

22. The display apparatus of claim 19, wherein a difference between the refractive index of the second functional layer and the refractive index of the first functional layer is about 0.05 to about 0.3.

23. The display apparatus of claim 19, further comprising an input sensing layer arranged between the thin-film encapsulation layer and the optical functional layer,
wherein the first functional layer is arranged to overlap a touch electrode of the input sensing layer.

24. The display apparatus of claim 19, further comprising:
a light-blocking layer disposed on the optical functional layer and comprising a first upper opening overlapping the first middle opening and a second upper opening overlapping the second middle opening; and
a first color filter filling the first upper opening and a second color filter filling the second upper opening.
